(19) United States
(12) Patent Application Publication
(10) Pub. No.: US 2005/0253236 A1
(43) Pub. Date: Nov. 17, 2005

(54) Semiconductor device capable of being connected to external terminals by wire bonding in stacked assembly

(75) Inventor: Akitomo Nakayama, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC.

(21) Appl. No.: 11/116,189

(22) Filed: Apr. 28, 2005

(30) Foreign Application Priority Data
Apr. 30, 2004 (JP) 2004-135312

(51) Int. Cl. H01L 23/02

(52) U.S. Cl. 257/678

(57) ABSTRACT

A semiconductor device includes a rectangular chip having four sides, wires connected respectively to different external terminals, and a bonding pad disposed along one of the four sides of the rectangular chip and directly connected to the wires for connection to the different external terminals. Since the different external terminals are bonded directly to the bonding pad by the wires, a signal input from one of the external terminals via one of the wires can be sent to the other external terminal via the other wire.

### BACKGROUND OF THE INVENTION

1. Field of the Invention

The present invention relates to a semiconductor device, a multi-chip package comprising a stack of semiconductor devices, and a wire bonding process for interconnecting pads of semiconductor devices.

2. Description of the Related Art

One example of a memory device that is referred to as a stack MCP (Multi-Chip Package) or simply an MCP, which comprises a stack of semiconductor device chips such as RAMs (Random Access Memories) or flash memories, is disclosed in Japanese laid-open patent publication No. 2003-7963 (hereinafter referred to as Patent Document 1).

A conventional MCP, which comprises a stack of a memory chip in the form of a DRAM (Dynamic Random Access Memory) and a CPU (Central Processing Unit) as a unit for controlling the memory chip, will be described below.

FIG. 1A of the accompanying drawings is a plan view showing an internal structure of the MCP, and FIG. 1B is a cross-sectional view taken along broken line 520-530 of FIG. 1A.

As shown in FIGS. 1A and 1B, memory chip 110 and CPU chip 130 are successively stacked on insulating board 300. As shown in FIG. 1B, memory chip 110 and CPU chip 130 have exposed upper surfaces covered with molded plastic layer 302.

As shown in FIG. 1A, each of memory chip 110 and CPU chip 130 is of an elongate rectangular shape having longer sides and shorter sides, and has a plurality of pads 2000 disposed along each of the shorter sides. Pads 2000 of CPU chip 130 and pads 2000 of memory chip 110 are interconnected by wire bonding. Pads 2000 on the shorter sides of CPU chip 130 and memory chip 110 are interconnected because the shorter sides of CPU chip 130 and memory chip 110 are of the same size, and the longer side of CPU chip 130 is longer than the longer side of memory chip 110, so that when CPU chip 130 and memory chip 110 are stacked, pads 2000 on the shorter sides thereof are exposed for interconnection by wire bonding.

CPU chip 130 also has a plurality of pads 2000 disposed along each of the longer sides thereof and connected to board pads 306 mounted on insulating board 300 by wire bonding. Board pads 306 on insulating board 300 are connected bumps 304 on the lower surface of insulating board 300 by interconnects (not shown).

Memory chip 110 of the MCP shown in FIGS. 1A and 1B will be described in detail below.

FIG. 2 of the accompanying drawings shows a circuit arrangement of memory chip 110.

As shown in FIG. 2, memory chip 110 has a storage area having memory elements which is divided into a plurality of banks 310A through 310D, a plurality of array control circuits 140A through 140D associated with respective banks 310A through 310D, a plurality of pads 2000 serving as terminals for receiving signals from and supplying signals to external circuits, peripheral circuit 150 for controlling signals between pads 2000 and array control circuits 140A through 140D, and a plurality of input protection circuits 160 disposed between respective pads 2000 and peripheral circuit 150.

Peripheral circuit 150 is disposed in a central region of memory chip 110 and regions between banks 310A through 310D and pads 2000.

Array control circuit 140A has a decoder selecting a desired memory element in bank 310A and a sense amplifier for amplifying a small potential difference developed in a selected bit line to a predetermined voltage. Array control circuits 140B through 140D are identical in construction to array control circuit 140A, and will not be described in detail below.

Peripheral circuit 150 has a signal controller for sending signals to array control circuits 140A through 140D for selecting memory elements from banks 310A through 310D, reading information from memory elements, and writing information in memory elements based on signals such as RAS (Row Address Strobe), CAS (Column Address Strobe), and WE (Write Enable) signals received from external circuits.

Each of input protection circuits 160 has protective devices for protecting a circuit against destruction due to an electrostatic discharge or a charge buildup discharge. Protective devices include an electrostatic breakdown prevention device for preventing a circuit from being destroyed by a human model (HM) or a machine model (MM), a resistive device serving as an input protection resistor, and a CDM (Charged Device Model) device for preventing a circuit from being destroyed by a charge buildup in a lead frame or the like. The CDM device and the electrostatic breakdown prevention device in a circuit are formed on the surface of a semiconductor substrate as with transistor devices in the circuit. The CDM device is a charge buildup destruction prevention device according to the present invention.

Pads 2000 include input pads serving as terminals for receiving signals from external circuits, output pads for supplying signals to external circuits, I/O pads serving as input and output terminals, power supply pads, and ground pads. The input pads include pads for RAS signals, pads for CAS signals, CS (Chip Select) pads for selecting chips, and address pads for specifying memory element addresses. FIG. 2 shows input pads 2000a and I/O pads 2000b as representing those pads.

FIG. 3 of the accompanying drawings is a block diagram showing circuit connections from the input pad and the I/O pad to the peripheral circuit in the circuit arrangement shown in FIG. 2.

As shown in FIG. 3, input protection circuit 160 comprises CDM device 161, resistive device 263, and electrostatic breakdown prevention device (EBP device) 162 which are disposed between input pad 2000a and the peripheral circuit (not shown). Input buffer 170 serving as an initial input stage circuit is connected to input pad 2000a. Input buffer 174 serves as a second stage input buffer following input buffer 170. Input buffer 171 serving as an initial input stage circuit and output buffer 172 serving as a final output stage circuit are connected to I/O pad 2000b. Output buffer 173 precedes output buffer 172 as the final output stage circuit, and input buffer 175 serves as a second stage input buffer following input buffer 171. These buffers are formed on the surface of the semiconductor substrate as with transistor devices in peripheral circuit 150 shown in FIG. 2.

The initial input stage circuit connected to input pad 2000a, and the initial input stage circuit and the final output stage circuit which are connected to I/O pad 2000b are disposed closely to these pads.

Another conventional MCP will be described below.

FIG. 4A of the accompanying drawings is a plan view showing an internal structure of the MCP, and FIG. 4B is a cross-sectional view taken along broken line 540-550 of FIG. 4A.

As shown in FIGS. 4A and 4B, memory chip 210 and CPU chip 230 are successively stacked on insulating board 300. As shown in FIG. 4B, memory chip 210 and CPU chip 230 have upper surfaces covered with molded plastic layer 302, and bumps 304 are disposed on the lower surface of insulating board 300, as with the MCP shown in FIGS. 1A and 1B.

As shown in FIG. 4A, each of memory chip 210 and CPU chip 230 is of an elongate rectangular shape having longer sides and shorter sides, and has a plurality of pads 2000 disposed along each of the longer sides. Pads 2000 of CPU chip 230 and pads 2000 of memory chip 210 are interconnected by wire bonding. Pads 2000 on the longer sides of CPU chip 230 and memory chip 210 are interconnected because the longer sides of CPU chip 230 and memory chip 210 are of the same size, and the shorter side of CPU chip 230 is shorter than the shorter side of memory chip 210, so that when CPU chip 230 and memory chip 210 are stacked, pads 2000 on the longer sides thereof are exposed for interconnection by wire bonding.

CPU chip 230 also has a plurality of pads 2000 disposed along each of the shorter sides thereof and connected to board pads 306 mounted on insulating board 300 by wire bonding. Board pads 306 on insulating board 300 are connected bumps 304 on the lower surface of insulating board 300 by interconnects (not shown).

Memory chip 210 of the MCP shown in FIGS. 4A and 4B will be described in detail below.

FIG. 5 of the accompanying drawings shows a circuit arrangement of memory chip 210. As shown in FIG. 5, memory chip 210 has a plurality of banks 310A through 310D, a plurality of array control circuits 240A through 240D, a plurality of pads 2000, peripheral circuit 250, and a plurality of input protection circuits 260. The functions of these circuits are the same as the circuits of memory chip 110 shown in FIG. 2, and will not be described in detail below.

On memory chip 210 shown in FIG. 5, peripheral circuit 250 is disposed in a central region of memory chip 210.

FIG. 6 of the accompanying drawings is a block diagram showing circuit connections from an input pad and an I/O pad to the peripheral circuit in the circuit arrangement shown in FIG. 5.

As shown in FIG. 6, input pad 2000a is connected to the peripheral circuit (not shown) by interconnect 280 on bank 310. Input protection circuit 260 comprises CDM device 161, electrostatic breakdown prevention device 162, and resistive device 263, which are disposed between input pad 2000a and the peripheral circuit. Resistive device 263 is disposed on interconnect 280 between CDM device 161 and electrostatic breakdown prevention device 162. Input buffer 270 serving as an initial input stage circuit is connected to input pad 2000a. I/O pad 2000b is connected by interconnect 281 to output buffer 271 serving as a final output stage circuit, and is also connected by interconnect 282 to input buffer 272 serving as an initial input stage circuit. The initial input stage circuit and the final output stage circuit are included in peripheral circuit 250 shown in FIG. 5.

Interconnect 281 has a width greater than interconnects 280, 282. An output signal that is transmitted through interconnect 281 and I/O pad 2000b to an external circuit needs to be amplified sufficiently so that the external circuit can receive the output signal without fail. Therefore, interconnect 281 has a width large enough to pass the amplified output signal therethrough.

Details of input protection circuits 260 will be described below. Input protection circuits 260 shown in FIG. 5 are identical in structure to input protection circuits 160 shown in FIG. 2. Consequently, input protection circuits 160 will be described below.

FIG. 7 of the accompanying drawings is a circuit diagram showing a circuit arrangement of each of input protection circuits 160.

As shown in FIG. 7, input protection circuit 160 has electrostatic breakdown prevention device 162, resistive device 263, and CDM device 161.

Electrostatic breakdown prevention device 162 is connected to first interconnect 157 which connects input pad 2000a and resistive device 263 to each other. Electrostatic breakdown prevention device 162 comprises diode 151 providing a junction made up of N-type diffused layer 164 and P-type diffused layer 165, P-channel transistor (hereinafter referred to as “P-ch Tr”) 152, and N-channel transistor (hereinafter referred to as “N-ch Tr”) 153. P-ch Tr 152 has a drain electrode connected to first interconnect 157, and gate and source electrodes connected to a power supply potential. N-ch Tr 153 has a drain electrode connected to first interconnect 157, and gate and source electrodes connected to a ground potential.

CDM device 161 is connected to second interconnect 158 which connects resistive device 263 to input buffer 170. CDM device 161 comprises N-ch Tr 155 and N-ch Tr 156. N-ch Tr 155 has a source electrode connected to second interconnect 158, a gate electrode connected to the ground potential, and a drain electrode connected to the power supply potential. N-ch Tr 156 has a drain electrode connected to second interconnect 158, and gate and source electrodes connected to the ground potential.

A signal that is input to input pad 2000a is supplied through first interconnect 157, to which electrostatic breakdown prevention device 162 is connected, resistive device 163, and second interconnect 158, to which CDM device 161 is connected, to input buffer 170. When a positive or negative high voltage is applied to input pad 2000a, the voltage is instantaneously discharged to GND (ground) or the power supply by the devices of input protection circuit 160 before the voltage reaches input buffer 170. Therefore, input buffer 170 is protected from undue high voltages.

In the above conventional MCP, the pads of the CPU chip are directly connected to the pads on the insulating board by wire bonding. A semiconductor device wherein pads of one of two semiconductor chips are connected via pads of the other semiconductor chip to pads on an insulating board by wire bonding is disclosed in Japanese laid-open patent publication No. 204720/99 (hereinafter referred to as Patent Document 2).

The above conventional MCP has a plurality of stacked semiconductor chips having different sizes. If a plurality of memory chips need to be stacked into an MCP for an increased storage capacity, then memory chips of the same size have to be stacked.

If a plurality of memory chips, each shown in FIG. 3 or FIG. 6, are simply stacked an upper memory chip covers a lower memory chip. In particular, it is difficult to perform wire bonding on a stack of equally sized chips having centrally positioned pads, such as LOC (Lead on Chip).

A stack of two memory chips and a CPU chip suffers the following problem: According to the conventional pad configuration, a single bonding wire is connected to one pad. For a CPU chip to access two memory chips, the CPU chip sends signals respectively to pads of the same functionality of the two memory chips. Therefore, one pad of the CPU chip needs to be connected to the pads of the two memory chips by respective bonding wires. Since the pad serving as a signal output source is connected to the plural pads, they are susceptible to an increased parasitic capacitance tending to a delay in the speed of signals transmitted between the pads and an increase in the level of power required to transmit signals. These problems make it difficult to maintain a signal drive frequency if two or more stacked chips are involved for inputting and outputting signals.

If three or more chips are stacked and the uppermost chip is connected to the lowermost chip, skipping the intermediate chip, by wire bonding, then bonding wires may possibly tend to contact the intermediate chip. Therefore, it is technically difficult to connect the uppermost chip directly to the lowermost chip, skipping the intermediate chip, according to wire bonding. In addition, bonding wires connected to pads that are widely spaced vertically are liable to cause a problematic parasitic capacitance.

The process disclosed in Patent Document 2 cannot directly be applied to an MCP having a stack of equally sized chips. Patent Document 2 discloses nothing specific about a process of connecting two bonding wires to one pad.

The conventional MCPs suffer not only the wire bonding problem mentioned above, but also have the following problems with respect to the memory chip circuit layout:

In the memory chip shown in FIG. 3, the peripheral circuit extends from the regions between the banks and the pads to the central region of the chip.

However, the peripheral circuit has a main circuitry disposed in the central region of the chip. Accordingly, each initial input stage circuit is spaced from the main circuitry of the peripheral circuit. It is difficult to satisfy high-speed requirements of the memory chip unless it is designed taking into account a signal propagation delay caused by CR values (capacitance and resistance values) of interconnects that connect the initial input stage circuit to the main circuitry of the peripheral circuit. Furthermore, the memory chip has a large power consumption requirement because the main circuitry of the peripheral circuit which is widely spaced from the initial input stage circuit needs to be driven.

In the memory chip shown in FIG. 6, since each initial input stage circuit is positioned closely to the main circuitry of the peripheral circuit, the connections from the pads to the initial input stage circuits need to be adjusted so that no skew will occur between the initial input stage circuits. Moreover, since the output buffer is spaced from each pad and connected thereto by the wide interconnect, the capacitance of the interconnect is large. The size of a transistor of the output buffer serving as the final output stage circuit is large because the transistor is required to send a high-power signal to the wide interconnect, resulting in an increase in the junction capacitance of the transistor. Accordingly, the propagation delay of the signal due to interconnect CR values is increased.

### SUMMARY OF THE INVENTION

It is an object of the present invention to provide a semiconductor device which is capable of being connected to external terminals by wire bonding when such semiconductor devices are stacked, a multi-chip package comprising a stack of such semiconductor devices, and a method of wire bonding between semiconductor devices.

According to the present invention, a semiconductor device includes a rectangular chip having four sides, wires connected respectively to different external terminals, and a bonding pad disposed along one of the four sides of said rectangular chip and directly connected to said wires for connection to said different external terminals.

Since the different external terminals are bonded directly to the bonding pad by the wires, a signal input from one of the external terminals via one of the wires can be sent to the other external terminal via the other wire. As the bonding pad is disposed along one of the four sides of the rectangular chip, the wires can easily be connected to the bonding pad closely to the external terminals. If a plurality of such semiconductor devices are stacked such that their pads are exposed, then their stacked area is increased, preventing the planar area of the stacked semiconductor device assembly from being increased.

The bonding pad may be of an elongate rectangular shape. With the bonding pad being of an elongate rectangular shape, if the joint of a single wire bonded to the bonding pad is of a circular shape and the diameter of the circular shape is smaller than one-half of the length of the longer sides of the bonding pad, then two or more wires can directly be bonded to the bonding pad.

In the semiconductor device according to the present invention, the bonding pad may have a plurality of unit pads each connectable to a single wire. Even if the wire bonded to one of the unit pads and the wire bonded to the other unit pad are connected to the different external terminals, respectively, since the unit pads are connected to each other by an interconnect, the wires are connected to each other.

In the semiconductor device, a plurality of the bonding pads may be disposed along the one of the four sides of the rectangular chip. As the bonding pads are disposed along one side, if a plurality of such semiconductor devices are stacked such that the sides thereof lie parallel to each other and their pads are exposed, then all the pads disposed along the sides can be bonded to external terminals by wire bonding, and the stacked area of the semiconductor devices is increased, preventing the planar area of the stacked semiconductor device assembly from being increased.

According to the present invention, a multi-chip package comprises a stacked assembly of first and second semiconductor devices each comprising the semiconductor device described above. The first semiconductor device has a first pad as the bonding pad and the second semiconductor device having a second pad as the bonding pad, and the first semiconductor device are positionally displaced with respect to the second semiconductor device in a direction perpendicular to the side along which the bonding pad is disposed, such that the first pad and the second pad are exposed, the first pad is connected to a first wire bonded to one of the external terminals, and the second pad is connected to the first pad by a second wire which is different from the first wire.

The semiconductor devices each have pads disposed along one side thereof and are stacked one on the other, with the sides being positionally displaced from each other in the direction perpendicular thereto such that the pads are exposed. Therefore, even if the first and second semiconductor devices are of the same size, the pads thereof can be connected by the second wire. Consequently, signals that are input from the external terminals can also be input to the second pad.

The multi-chip package according to the present invention may further comprise a third semiconductor device having the one of the external terminals and stacked on the first semiconductor device such that the first pad is exposed. The third semiconductor device is stacked on the first semiconductor device, and the external terminal of the third semiconductor device is connected to the first pad, which is connected to the second pad. Therefore, a signal output from the external terminal of the third semiconductor device is input to the first and second semiconductor devices. The third semiconductor device can thus send common signals to the first and second semiconductor devices.

In the multi-chip package, the first pad may be electrically insulated from an internal circuit of the first semiconductor device. As the first pad is electrically insulated from the internal circuit of the first semiconductor device, a signal output from the external terminal of the third semiconductor device is not input to the first semiconductor device, but input to the second semiconductor device. Therefore, the third semiconductor device can send a signal for selecting the second semiconductor device. In the multi-chip package, at least one of the first and second semiconductor devices may comprise a storage area divided into a plurality of banks, a peripheral circuit connected to the banks and spaced equally from the banks, for processing signals transferred between the banks and an external circuit, and buffers connected to the peripheral circuit and positioned more closely to the pads than the peripheral circuit, for amplifying output signals to be supplied to the external circuit.

Inasmuch as the peripheral circuit is spaced equally from the banks and the buffers for amplifying output terminals are positioned more closely to the pads than the peripheral circuit, if the peripheral circuit is surrounded by the banks, the buffers are disposed between the pads and the banks. As output signals are amplified more closely to the pads than the banks, the electric power consumed by the multi-chip package is smaller than high-power signals are output from the peripheral circuit.

In the multi-chip package, at least one of the first and second semiconductor devices may comprise an interconnect connecting the pads which are supplied with signals from the external circuit to the peripheral circuit, a first input protection circuit connected to the interconnect more closely to the peripheral circuit than the banks, and a second input protection circuit connected to the interconnect more closely to the pads than the first input protection circuit and disposed between the pads and the banks.

Because the first input protection circuit and the second input protection circuit are connected to the interconnect across the banks, the resistance imposed by the length of the interconnect extending on the banks serves as a device for preventing the circuit of the semiconductor device from being destroyed.

According to the present invention, there is also provided a method of wire bonding between a first semiconductor device having a first pad having wire bonding areas capable of directly bonding a plurality of wires thereto and a second semiconductor device having a second pad having a wire bonding area capable of bonding at least one wire thereto, comprising the steps of bonding a first wire connected to an external terminal to the first pad, bonding a second wire to the first pad, and bonding the second wire to the second pad.

Since the second pad is connected to the external terminal through the first pad, a wire does not need to be bonded directly from the external terminal to the second pad. Because there is not wire bonded directly from the external terminal to the second pad, the parasitic capacitance which is greater as the wires are longer is reduced.

According to the present invention, even if a plurality of chips of one size are stacked, the chips can be interconnected by wire bonding. If the chips comprise memories stacked in a memory package, then the memory capacity of the memory package can be at least twice the memory capacity of a conventional memory package. The area of each of the chips is prevented from being increased, and the signal processing in the memory package can be speeded up.

In the memories of the multi-chip package, the buffers serving as a final output stage circuit for signals are disposed closely to the pad. The distances from the buffers to the pads are thus shorter than heretofore, reducing the load imposed on the buffers by interconnect CR values. Furthermore, since the buffers serving as the final output stage circuit are not disposed in the peripheral circuit, but positioned closely to the pads, interconnects from the buffers to the peripheral circuit are thin in width, and the interconnect capacitance is small.

The above and other objects, features, and advantages of the present invention will become apparent from the following description with reference to the accompanying drawings which illustrate examples of the present invention.

### BRIEF DESCRIPTION OF THE DRAWINGS

FIG. 1A is a plan view showing an internal structure of a conventional MCP;

FIG. 1B is a cross-sectional view of the conventional MCP shown min FIG. 1A;

FIG. 2 is a block diagram of a circuit arrangement of a memory chip of the MCP shown in FIGS. 1A and 1B;

FIG. 3 is a block diagram of circuit connections from an input pad and an I/O pad to a peripheral circuit in the circuit arrangement shown in FIG. 2;

FIG. 4A is a plan view showing an internal structure of another conventional MCP;

FIG. 4B is a cross-sectional view of the conventional MCP shown min FIG. 4A;

FIG. 5 is a block diagram of a circuit arrangement of a memory chip of the MCP shown in FIGS. 4A and 4B;

FIG. 6 is a block diagram of circuit connections from an input pad and an I/O pad to a peripheral circuit in the circuit arrangement shown in FIG. 5;

FIG. 7 is a circuit diagram showing a circuit arrangement of each of input protection circuit;

FIGS. 8A and 8B are plan views showing an arrangement of an MCP according to a first embodiment of the present invention;

FIG. 9 is a cross-sectional view of the MCP shown in FIGS. 8A and 8B;

FIGS. 10A, 10B, and 10C are enlarged fragmentary plan views showing other pads;

FIG. 11 is a block diagram of a circuit arrangement of a memory chip of the MCP shown in FIGS. 8A and 8B;

FIG. 12 is a plan view of the memory chip shown in FIG. 11;

FIG. 13 is a plan view showing the manner in which signals are sent and received in the memory chip shown in FIG. 11;

FIGS. 14A, 14B, and 14C are fragmentary cross-sectional views illustrative of a wire bonding process for the MCP shown in FIG. 9; and

FIG. 15 is a cross-sectional view of a semiconductor device according to a second embodiment of the present invention.

### DETAILED DESCRIPTION OF THE PREFERRED EMBODIMENTS

Semiconductor devices according to the present invention reside in that they include pads having areas which are capable of connecting themselves directly to wires that are connected to different external terminals.

### 1st Embodiment

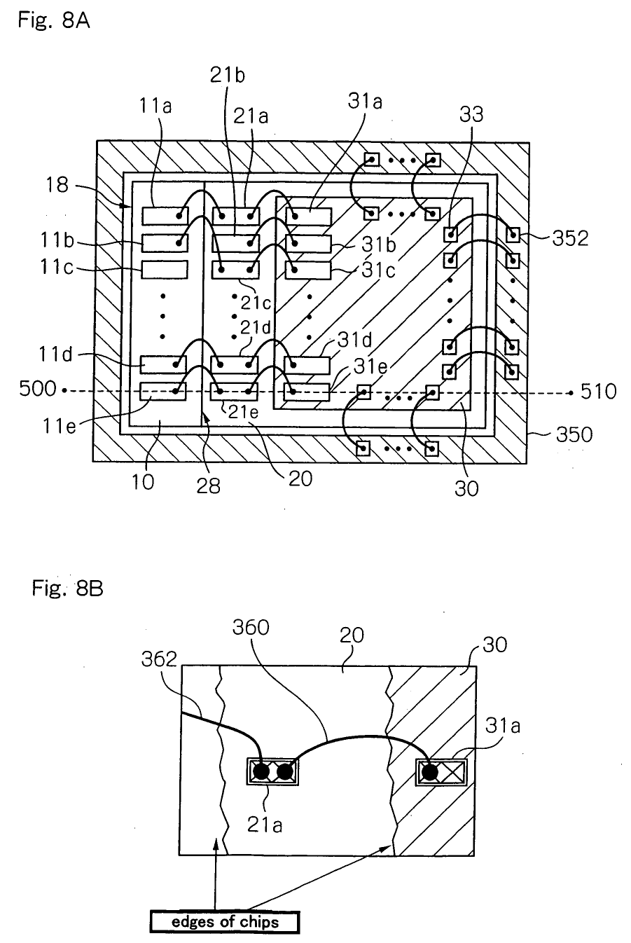

FIG. 8A is a plan view showing an arrangement of an MCP according to a first embodiment of the present invention, and FIG. 8B is an enlarged plan view of pads of the MCP shown in FIG. 8A.

As shown in FIG. 8A, the MCP has lower memory chip 10, upper memory chip 20, and CPU chip 30 as a unit for controlling lower and upper memory chips 10, 20. Lower and upper memory chips 10, 20 are of the same type and the same size. Lower memory chip 10 has pads 11a through 11e disposed closely to and along one side 18 thereof. Similarly, upper memory chip 20 has pads 21a through 21e disposed closely to and along one side 28 thereof, and CPU chip 30 has pads 31a through 31e disposed closely to and along one side thereof.

Upper memory chip 20 is stacked on lower memory chip 10 with side 28 being positionally displaced from side 18 in a direction perpendicularly thereto such that pads 11a through 11e of lower memory chip 10 are exposed. CPU chip 30 is stacked on upper memory chip 20 such that pads 21a through 21e of upper memory chip 20 are exposed. Each of pads 11a through 11e, 21a through 21e, 31a through 31e is of a rectangular shape which is elongate, i.e., whose longer sides extend, in the direction in which the sides of the chips are positionally displaced.

Pads 31b, 31c of CPU chip 30 serve as output terminals for supplying CS (Chip Select) signals, pad 21b of upper memory chip 20 serves as input terminal for receiving CS signal, and pad 11b of lower memory chip 10 serves as input terminal for receiving CS signal. Pad 31b is connected to pad 21b, and pad 21b is not connected to lower memory chip 10. Pad 31c is connected through pad 21c to pad 11b of lower memory chip 10, and pad 21c is electrically insulated from circuits on upper memory chip 20. When CPU chip 30 selects lower memory chip 10, CPU chip 30 sends a CS signal from pad 31c through pad 21c to pad 11b. When CPU chip 30 selects upper memory chip 20, CPU chip 30 sends a CS signal from pad 31b to pad 21b.

Pads 31a, 31d, 31e of CPU chip 30 serve as output terminals for supplying signals common to memory chips 10, 20, such as address and WE signals. Pad 31a is connected through pad 21a to pad 11a, pad 31d through pad 21d to pad 11d, and pad 31e through pad 21e to pad 11e.

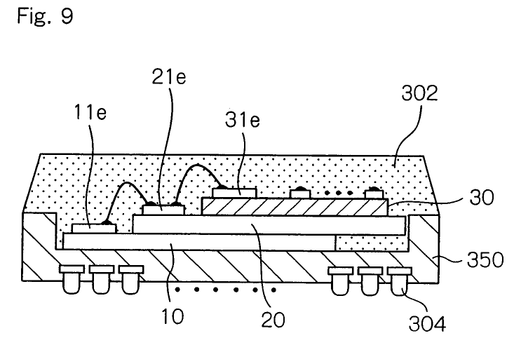

CPU chip 30 has other pads 33 connected to board pads 352 mounted on insulating board 350. Board pads 352 are connected bumps 304 (see. FIG. 9) on the lower surface of insulating board 350 by interconnects (not shown) for sending signals to and receiving signals from external devices via bumps 304.

FIG. 8B shows wire bonding areas, indicated by “x”, on pads 21a, 31a.

As shown in FIG. 8B, wires 360, 362 are bonded to the respective two wire bonding areas “x” on pad 21a. Pad 21a has a shorter side which is 50 μm long and a longer side which is 100 μm long. In a wire bonding process based on the ultrasonic thermocompression technique, the diameter of the ball formed on the tip end of the wire and pressed against the wire bonding area of the bonding pad is normally greater than the diameter of the wire used. If a wire having a diameter ranging from 20 to 30 μm is used for wire bonding, then the diameter of the pressed ball is in the range from 40 to 50 μm. However, the above pad dimensions keep the ball on the tip end of the wire within the wire bonding area transversely across pad 21a.

When one wire is bonded to one of the two wire bonding areas, the other wire bonding area, which is at least 50 μm×50 μm wide, is still available on the pad, and another wire may be bonded to the other wire bonding area. Since pad 21a thus has two wire bonding areas, two wires can directly be bonded to pad 21a without overlapping. Pad 31a also has two wire bonding areas, indicated by “x”, and allow two wires to be bonded thereto.

FIG. 9 is a cross-sectional view of the MCP shown in FIG. 8A, taken along broken line 500-510 of FIG. 8A.

Lower and upper memory chips 10, 20 are of the same type and the same size. As shown in FIG. 9, upper memory chip 20 is positionally displaced to the right on lower memory chip 10 such that the pads on lower memory chip 10, which need to be connected to wires by wire bonding, are exposed. Therefore, as shown in FIG. 8A, the pads on lower memory chip 10 are readily accessible for wire bonding.

Other pads for use in the MCP according to the present embodiment will be described below.

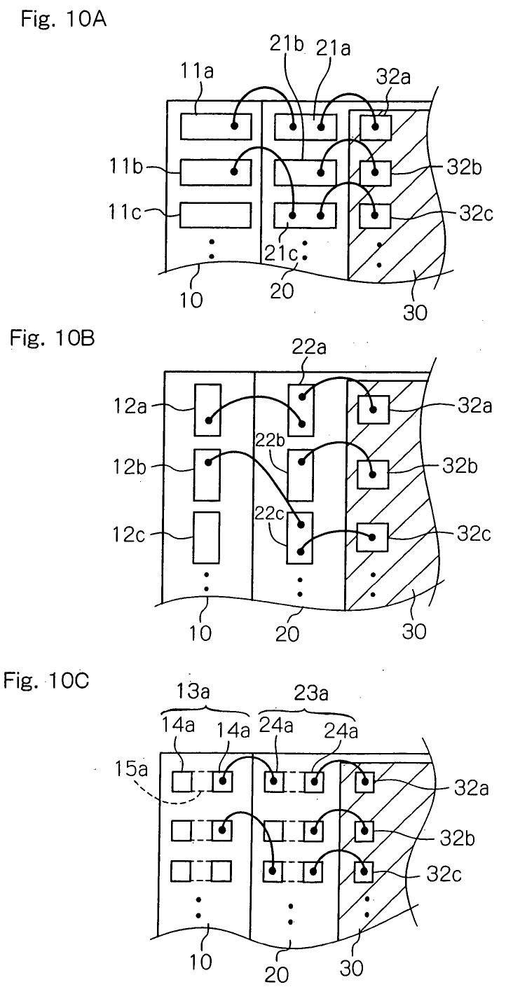

FIGS. 10A, 10B, and 10C are enlarged fragmentary plan views showing other pads for use in the MCP.

FIG. 10A shows pads of lower memory chip 10, upper memory chip 20, and CPU chip 30. The pads shown in FIG. 10A are similar to those shown in FIG. 8A except that the pads on CPU chip 30 are of a square shape.

Pads 32a, 32b, 32c of CPU chip 30 may be of a square shape because only one wire is bonded to each of pads 32a, 32b, 32c. The pads of lower memory chip 10 and upper memory chip 20 are interconnected by wires in the same patter as shown in FIG. 8A.

FIG. 10B shows other pads of lower memory chip 10, upper memory chip 20, and CPU chip 30. Each of the pads of lower memory chip 10 and upper memory chip 20 is of a rectangular shape whose longer sides extend perpendicularly to the direction in which the sides of the chips are positionally displaced. These pads can be arranged as shown in FIG. 10B if the longer sides of the pads can be arranged along the sides of lower memory chip 10 and upper memory chip 20. Pad 32a is connected through pad 22a to pad 12a. Pads 32b, 32c serve as output terminals for supplying CS signals. Pad 32b is connected to pad 22b, which is not connected to lower memory chip 10. Pad 32c is connected through pad 22c to pad 12b.

If pad 21a shown in FIG. 10A has its shorter sides extended twice in length, then four wires can be bonded to pad 21a. This modification is also applicable to the other pads of upper memory chip 20 and pads 11a through 11e of lower memory chip 10 shown in FIG. 10A, and also to the pads of upper memory chip 20 and lower memory chip 10 shown in FIG. 10B.

FIG. 10C shows still other pads of lower memory chip 10, upper memory chip 20, and CPU chip 30. In FIG. 10C, each of the pads of lower memory chip 10 and upper memory chip 20 comprises two unit pads each having a wire bonding area to which a single wire can be bonded, the two unit pads being connected to each other by an interconnect. Pad 13a of lower memory chip 10 comprises two unit pads 14a connected to each other by interconnect 15a. Similarly, pad 23a of upper memory chip 20 comprises two unit pads 24a connected to each other by an interconnect. The other pads of lower memory chip 10 and upper memory chip 20 are of the same structure as pads 13a, 23a.

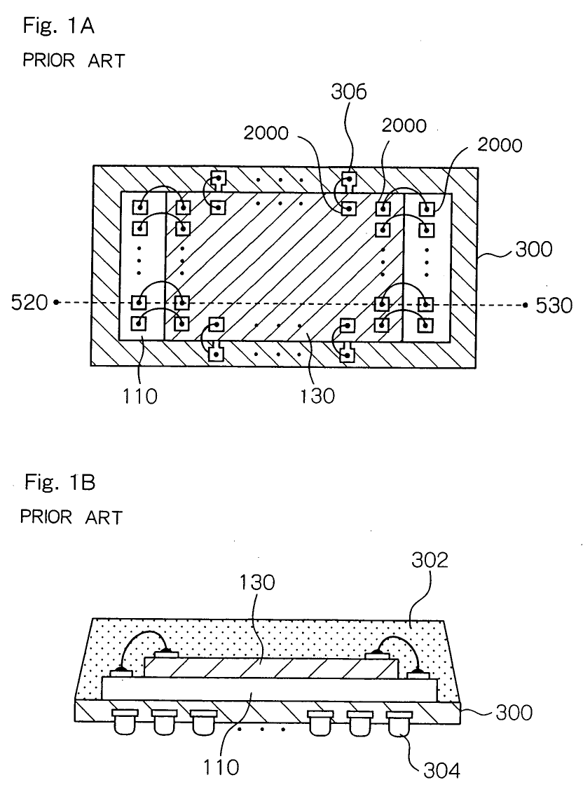

As shown in FIG. 1C, one of two unit pads 24a of pad 23a of upper memory chip 20 is connected to pad 32a of CPU chip 30, and the other to one of two unit pads 14a of lower memory chip 10. The interconnects which connect between the unit pads are covered with an insulating film. Each of the pads may comprise more than two unit pads.

The memory chips of the MCP shown in FIG. 8A will be described below. Since lower memory chip 10 and upper memory chip 20 are identical in structure to each other, structural details of lower memory chip 10, but not upper memory chip 20, will be described below.

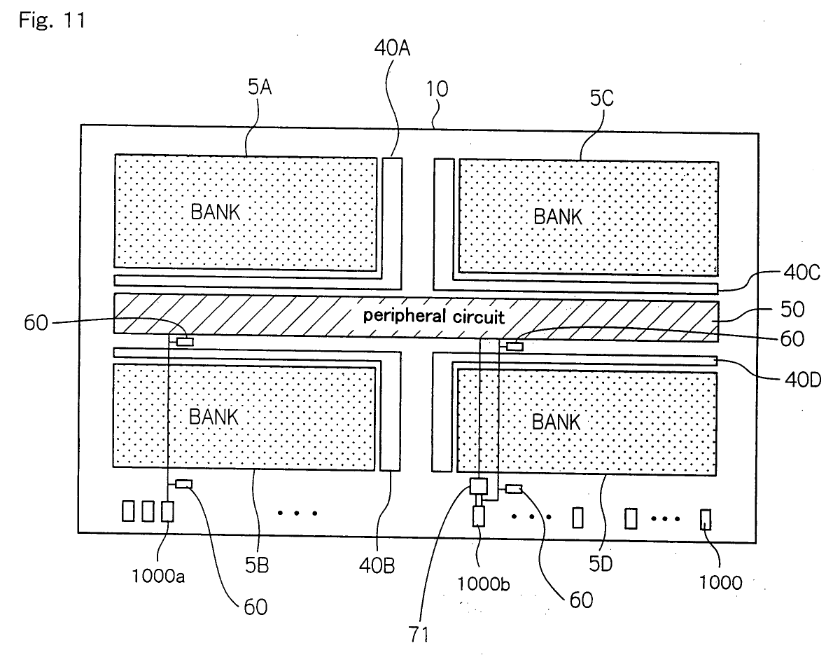

FIG. 11 shows in block form a circuit arrangement of lower memory chip 10. The layout of pads shown in FIG. 11 is different from the layout of pads shown in FIG. 8A with respect to the types of input and output signals.

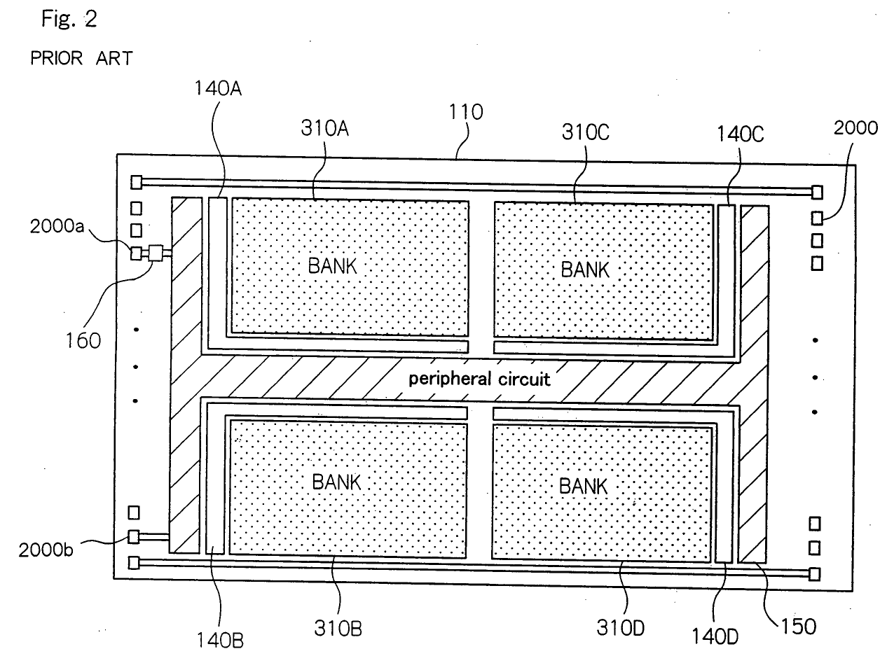

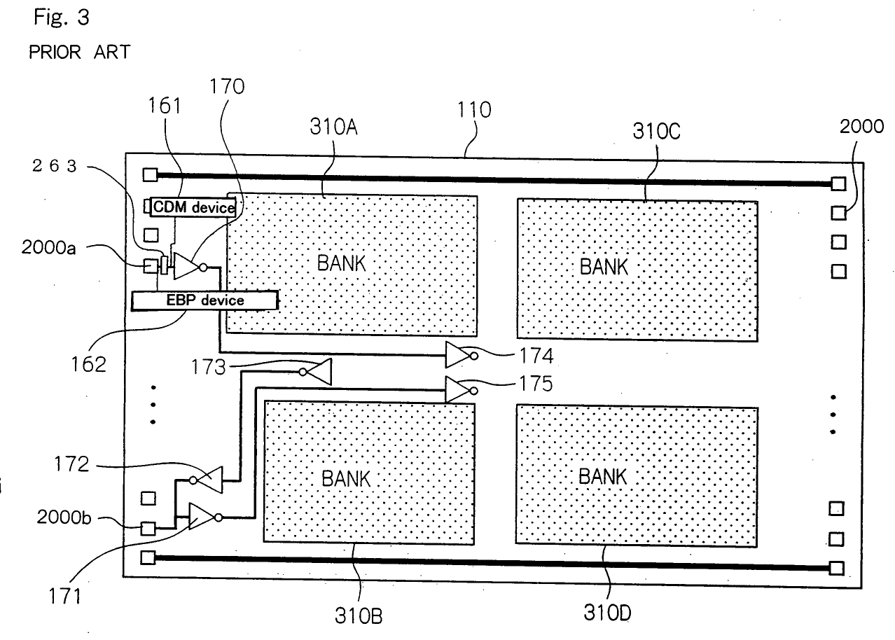

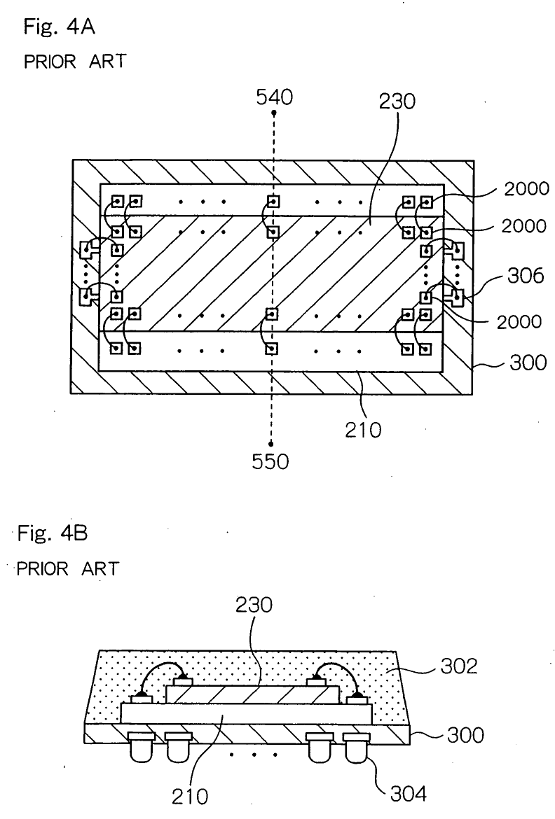

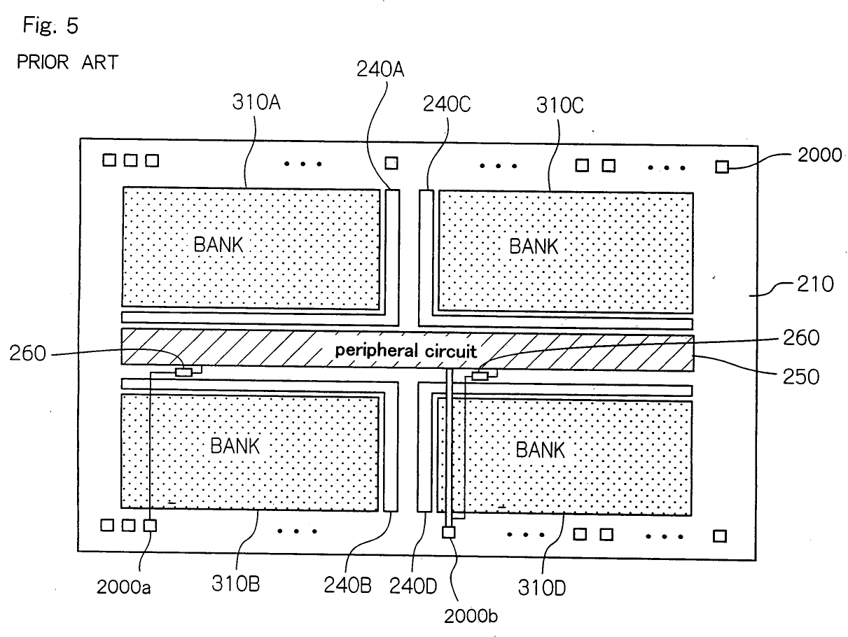

Lower memory chip 10 shown in FIG. 11 has banks 5A through 5D, array control circuits 40A through 40D, a plurality of pads 1000, peripheral circuit 50, and input protection circuit 60. Peripheral circuit 50 is sandwiched between banks 5A, 5C and banks 5B, 5D, and is disposed at equal distances from the banks. The functions of the circuits are the same as those of conventional memory chip 110 shown in FIG. 2, and will not be described in detail below. Only a representative pad is denoted by 1000.

All pads 1000 are disposed along one of the two longer sides of lower memory chip 10 and more closely to the edge of lower memory chip 10 than lower banks 5B, 5D shown in FIG. 11. Each of pads 1000 has an elongate rectangular shape and has shorter sides lying parallel to the longer sides of lower memory chip 10.

According to the present embodiment, as shown in FIG. 11, output buffer 71 serving as a final output stage circuit for a signal that is output from I/O pad 1000b is positioned more closely to I/O pad 1000b than peripheral circuit 50.

Circuit connections from pad 1000 to peripheral circuit 50 will be described below.

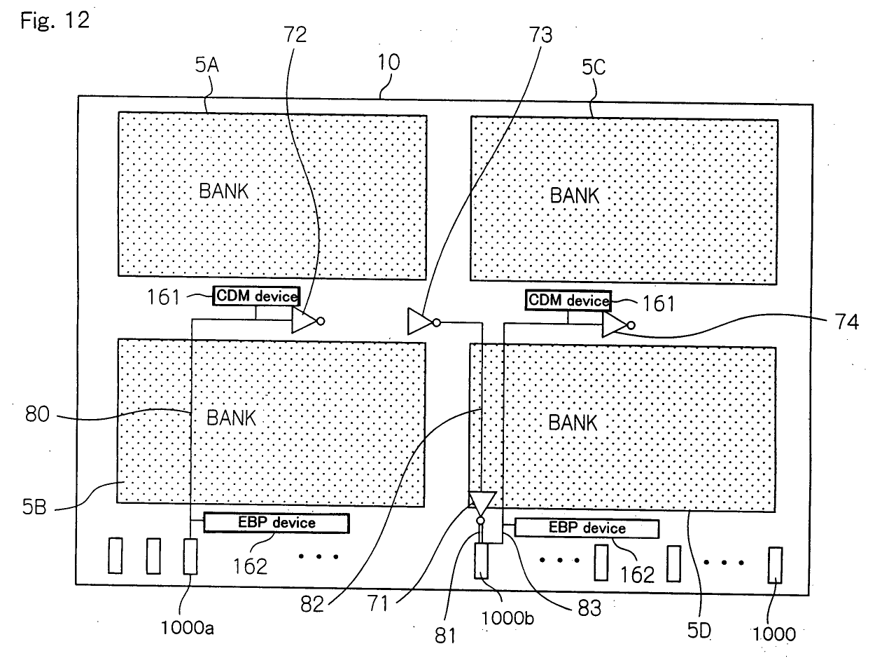

FIG. 12 shows circuit connections from an input pad and an I/O pad to a peripheral circuit in the memory chip shown in FIG. 11.

As shown in FIG. 12, input pad 1000a is connected through interconnect 80 on bank 5B to input buffer 72 serving as an initial input stage circuit in peripheral circuit 50. According to the present embodiment, electrostatic breakdown prevention device 162 of input protection circuit 60 is disposed between input pad 1000a and bank 5B and connected to interconnect 80. CDM device 161 of input protection circuit 60 is disposed between bank 5B and peripheral circuit 50 and connected to interconnect 80.

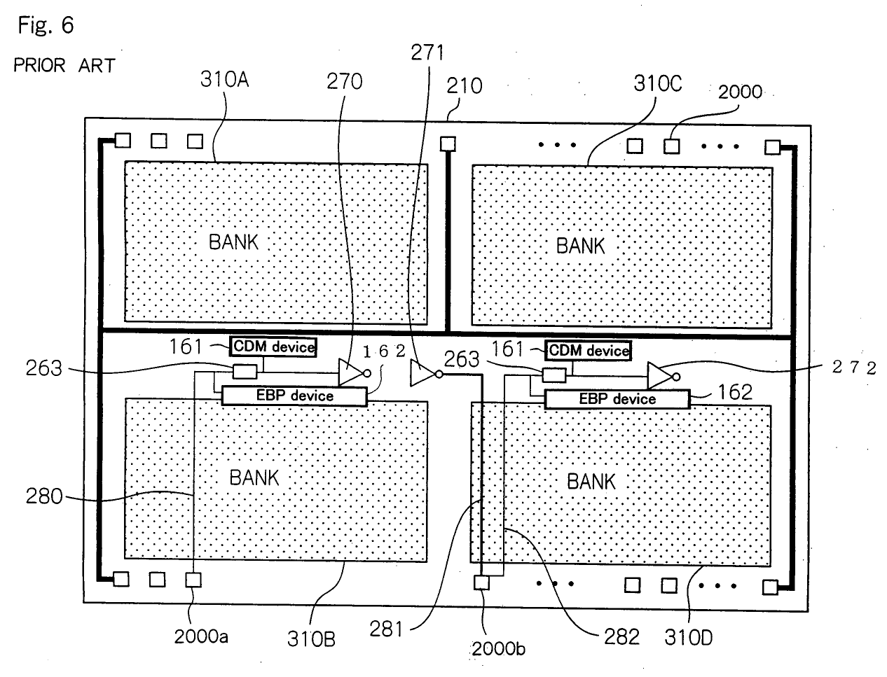

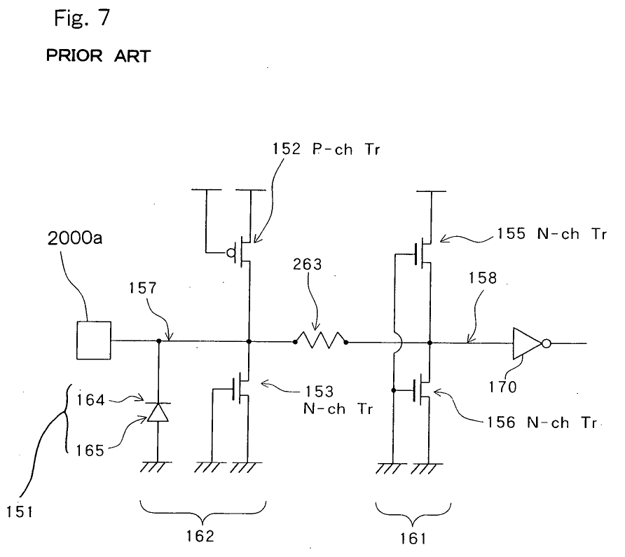

Conventionally, as shown in FIG. 6, resistive device 263 is disposed between electrostatic breakdown prevention device 162 and CDM device 161. According to the present embodiment, however, the resistance of resistive device 263 is replaced with the resistance imposed by the length of interconnect 80. Therefore, conventional resistive device 263 is dispensed with.

Output buffer 71 serving as a final output stage circuit is disposed between I/O pad 1000b and bank 5D. I/O pad 1000b is connected through interconnect 81 to output buffer 71. Output buffer 71 is connected through interconnect 82 on bank 5D to output buffer 73 in peripheral circuit 50.

Since the final output stage circuit is disposed in a line for supplying a signal to an external circuit closely to I/O pad 1000b that is positioned across bank 5D from peripheral circuit 50, a signal to be transmitted to the final output stage circuit may be of a low power, making it possible to make interconnect 82 narrower than interconnect 81. Therefore, the width of interconnect 82 on bank 5D does not need to be as large as the width of the conventional interconnect. Furthermore, the distance from output buffer 71 to I/O pad 1000b is shorter than the conventional distance, reducing the load imposed on output buffer 71 by the interconnect CR values. Heretofore, a high-power signal has been transmitted through a wider and longer interconnect. According to the present invention, however, a low-power signal may be transmitted through a narrower interconnect, thereby making power consumption smaller than heretofore. As interconnect 82 disposed on bank 5D for transmitting an output signal may be narrower than heretofore, the capacitance of interconnect 82 is smaller, and interconnect 82 is prevented from interfering with an interconnect pattern which should be wide, such as a power supply line.

I/O pad 1000b is also connected through interconnect 83 disposed on bank 5D to input buffer 74 serving as an initial input stage circuit in peripheral circuit 50. Electrostatic breakdown prevention device 162 of input protection circuit 60 is disposed between I/O pad 1000b and bank 5D and connected to interconnect 83. CDM device 161 of input protection circuit 60 is disposed between bank 5B and peripheral circuit 50 and connected to interconnect 83.

In a line for transmitting an input signal from I/O pad 1000b, the resistance of resistive device 263 is replaced with the resistance imposed by the length of interconnect 83, as with the circuit connection from input pad 1000a to peripheral circuit 50. Therefore, conventional resistive device 263 is also dispensed with.

A circuit layout in lower memory chip 10 shown in FIG. 11 will be described below.

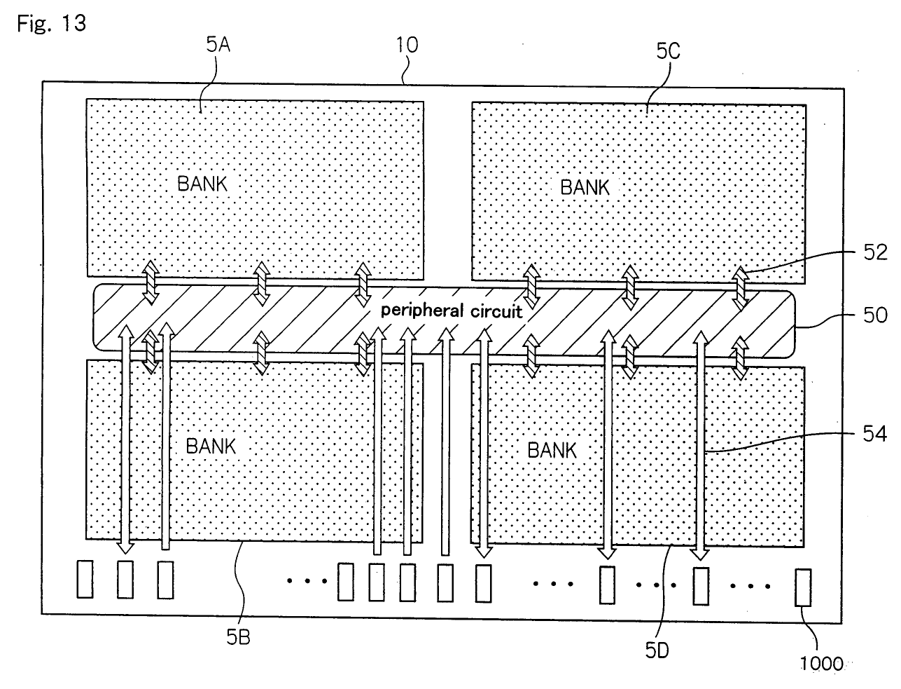

FIG. 13 shows the manner in which signals are sent and received in the lower memory chip according to the present embodiment.

Generally, a peripheral circuit positioned more closely to pads of a semiconductor device allows signals to be sent and received at higher speeds between external circuits and the peripheral circuit, making it possible to operate the semiconductor device at a higher speed.

In the memory chip shown in FIG. 11 where pads 1000 are disclosed along one longer side of the memory chip, if a peripheral circuit is disposed closely to pads 1000, then since banks 5B, 5D are close to the peripheral circuit, signals can be sent and received at higher speeds between banks 5B, 5D and the peripheral circuit. However, though banks 5B, 5D are positioned closely to the peripheral circuit, banks 5A, 5C are positioned farther from the peripheral circuit than banks 5B, 5D, so that signals are sent and received at lower speeds between banks 5A, 5C and the peripheral circuit. If signals are sent and received at different speeds depending on the bank that is accessed thereby, then the circuits of the memory chip have to be designed to equalize all the signal speeds to the slowest signal speed, and hence the operating speed of the memory chip or semiconductor device has to be lowered.

According to the present embodiment, as shown in FIG. 11, peripheral circuit 50 is sandwiched between banks 5A, 5C and banks 5B, 5D.

Consequently, signals are sent and received between these banks and peripheral circuit 50 at substantially equal speeds for the banks, as indicated by the arrows 52 in FIG. 13. In addition, because the distances between peripheral circuit 50 and the pads are substantially equal, signals are sent and received between peripheral circuit 50 and the pads at substantially constant speeds for the pads, as indicated by the arrows 54 in FIG. 13.

A wire bonding process for the MCP will be described below.

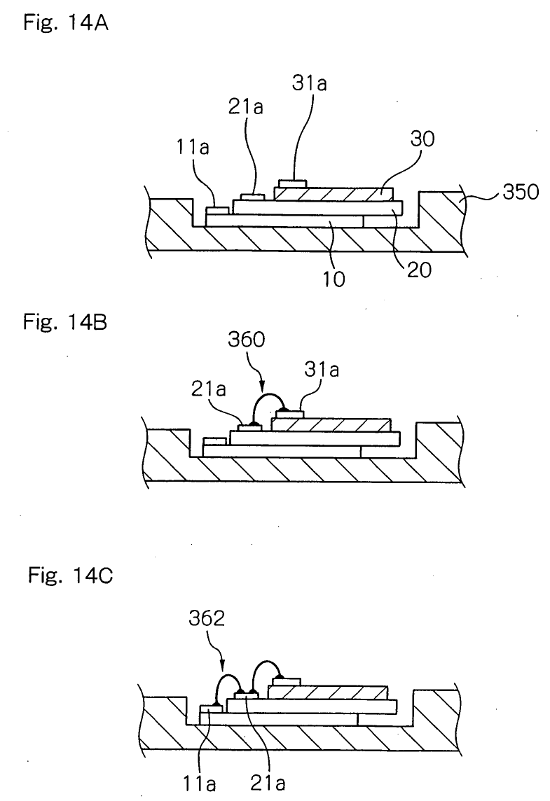

FIGS. 14A, 14B, and 14C are fragmentary cross-sectional views illustrative of a wire bonding process for the MCP shown in FIG. 9. The wire bonding process, as performed on pads 31a, 21a, 11a, will be described below. Other pads are omitted from illustration. It is assumed that each of pads 31a, 21a, 11a has an elongate rectangular shape having a size of 100 μm×50 μm, and a wire used in the wire bonding process has a diameter in the range from 20 to 30 μm.

Lower memory chip 10, upper memory chip 20, and CPU chip 30 have respective surfaces on which the pads are disposed, and those surfaces, except for the pads, are covered with a wafer coating layer or the like for circuit protection. As shown in FIG. 14A, insulating board 350 is coated with an adhesive and lower memory chip 10 is placed thereon. Then, lower memory chip 10 is coated with an adhesive, and upper memory chip 20 is placed thereon. Upper memory chip 20 is positionally displaced to the right in FIG. 14A on lower memory chip 10 such that pad 11a of lower memory chip 10 is not covered with upper memory chip 20. Thereafter, upper memory chip 20 is coated with an adhesive, and CPU chip 30 is stacked thereon.

As shown in FIG. 14B, based on the ultrasonic thermocompression technique, wire 360 is bonded to pad 31a and then to pad 21a. Specifically, wire 360 is bonded to one half of the area of pad 21a which is closer to CPU chip 30.

Then, as shown in FIG. 14C, based on the ultrasonic thermocompression technique, wire 362 is bonded to the remaining half of the area of pad 21a, and then to pad 11a.

Since pad 21a has two wire bonding areas, it is possible to bond wire 360 and wire 362 to pad 21a.

If three or more chips are stacked, then the uppermost chip and the lowermost chip are widely spaced from each other. The uppermost chip and the lowermost chip can be electrically connected to each other by bonding wires from the uppermost chip to the intermediate chip and then from the intermediate chip to the lowermost chip, rather than by bonding wires directly between the uppermost chip and the lowermost chip.

In the present embodiment, wires are bonded from the upper chip to the lower chip. However, wires may be bonded from the lower chip to the upper chip.

With the semiconductor device according to the present invention, since different external terminals can directly be bonded to a pad by wires, a signal input from one of the external terminal via one of the wires may be sent to the other external terminal through the other wire.

As pads are disposed along one of the four sides of a chip, the wires can easily be connected to the pads closely to external terminals such as pads of another chip. If a plurality of such chips or semiconductor devices are stacked such that their pads are exposed, then their stacked area is increased, preventing the planar area of the stacked semiconductor device assembly from being increased.

Since pads are disposed along one side of a chip, if a plurality of such chips or semiconductor devices are stacked such that the sides thereof lie parallel to each other and their pads are exposed, then all the pads disposed along the sides can be bonded to external terminals by wire bonding, and the stacked area of the semiconductor devices is increased, preventing the planar area of the stacked semiconductor device assembly from being increased.

In the MCP according to the present embodiment, two memory chips each having pads disposed along one side thereof are stacked one on the other, with the sides being positionally displaced from each other in the direction perpendicular thereto such that the pads are exposed. Therefore, even if the memory chips are of the same size, the pads of the memory chips can be connected by bonding wires. Consequently, signals that are input from external terminals to one of the memory chips can also be input to the other memory chip via the bonding wires.

Furthermore, a CPU chip is stacked on the upper one of the two memory chips and has external terminals connected to the pads of the upper memory chip, and the pads of the upper memory chip are connected to the pads of the lower memory chip. Therefore, signals output from the external terminal of the CPU chip are input to the two memory chips. Accordingly, the CPU chip can send common signals to the two memory chips.

Moreover, in an MCP comprising a CPU chip and two memory chips, pads that are electrically insulated from internal circuits are disposed on the upper memory chip, and the CPU chip is connected to the lower memory chip via the pads of the upper memory chip. With this arrangement, signals output from the CPU chip are not input to the upper memory chip, but applied to the lower memory chip. Therefore, the CPU chip can send signals to select the lower memory chip.

In an MCP comprising three or more chips, the uppermost chip is electrically connected to the lowermost chip by bonding wires from the uppermost chip to the intermediate chip and then from the intermediate chip to the lowermost chip, rather than by bonding wires directly between the uppermost chip and the lowermost chip, skipping the intermediate chip. In this manner, the parasitic capacitance which is greater as the wires are longer is reduced. In a memory chip according to the present embodiment, since a peripheral circuit is disposed at equal distances from banks, signal processing operation is optimized, a clock skew is reduced, and signals can be processed at high speeds.

### 2nd Embodiment

According to a second embodiment of the present invention, an MCP comprises three stacked memory chips.

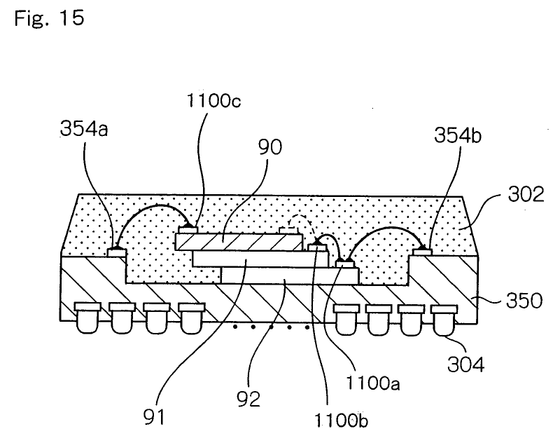

FIG. 15 shows in cross section an MCP according to the second embodiment of the present invention.

As shown in FIG. 15, the MCP has two flash memories 91, 92 and DRAM 90. DRAM 90 may be replaced with an SRAM (Static Random Access Memory).

As shown in FIG. 15, two flash memories 91, 92 are stacked one on the other as with the memory chips according to the first embodiment, and DRAM 90 is stacked on flash memory 91. As with the first embodiment, pads of flash memories 91, 92 and DRAM 90 are connected by bonding wires for performing desired operation between flash memories 91, 92 and DRAM 90. The pads of flash memories 91, 92 which are connected to the pads of DRAM 90 are related thereto in the same manner as heretofore, and such connections will not be described in detail below.

As with the first embodiment, pad 1100c of DRAM 90 as an uppermost layer is connected to board pad 354a that is connected to bump 304 through an interconnect (not shown).

According to the second embodiment, pad 1100a of flash memory 92 as a lowermost layer is connected to board pad 354b of insulating board 350 and also to pad 1100b of flash memory 91 as an intermediate layer. Board pad 354b serves as a terminal for connection to a power supply or a ground terminal.

Flash memories 91, 92 as the intermediate and lowermost layers may thus be connected to the power supply and the ground potential via board pad 354b of insulating board 350, rather than via DRAM 90.

Pad 1100a and pad 1100b may not be connected to each other, but pad 1100b may directly be connected to board pad 354b for connection to the power supply or the ground terminal. Alternatively, as indicated by the broken line in FIG. 15, pad 1100b may be connected to a pad of DRAM 90 to connect DRAM 90 to the power supply or the ground terminal via flash memories 91, 92. Pads 1100a, 1100b of flash memories 91, 92 are not limited to being connected to the power supply or the ground terminal, but may be used as pads for supplying control signals for inputting data to and outputting data from flash memories 91, 92.

In the MCP comprising the DRAM and the flash memories according to the second embodiment, it is possible to send information stored in the DRAM successively to the flash memories.

In the first and second embodiments, three semiconductor chips are stacked together. However, four or more semiconductor chips may be stacked together.

A memory control chip stacked on memory chips is not limited to a CPU chip, but may be a memory controller.

In the first embodiment, as in the second embodiment, the two lower chips may be connected to the power supply and the ground potential by bonding wires directly to board pads 352 of insulating board 350.

In the first embodiment, if upper memory chip 20 shown in FIG. 8A can be further be positionally displaced to the right to provide a wider exposed area of lower memory chip 10, then pad 11a on the upper side and pad 11e on the lower side of lower memory chip 10 may be disposed in advance at a position that is displaced to the right. For example, if pads 11a, 11e of lower memory chip 10 are positionally displaced to the right by a distance equal to the length of the longer sides of pad 11a, then upper memory chip 20 is positionally displaced from the position shown in FIG. 8A to the right by the distance equal to the length of the longer sides of pad 11a, and stacked on lower memory chip 10. Upper memory chip 20 thus positionally displaced allows wires to be bonded to pads 11a, 11e. Though both pads 11a, 11e have been described as being positionally displaced by the distance equal to the length of the longer sides thereof, either one of pads 11a, 11e may be positionally displaced, and one or both of pads 11a, 11e may be positionally displaced to the right by a distance that is not equal to the length of the longer sides thereof. The above positional displacement of the pads and the chips is also applicable to the second embodiment, and does not depart from the scope of the invention.

In the second embodiment, the flash memories have been illustrated as nonvolatile memories. However, other nonvolatile memories such as an EEPROM (Electrically Erasable and Programmable Read Only Memory), etc. may be employed.

Input protection circuit 160 is not limited to comprising an electrostatic breakdown prevention device, a resistive device, and a CDM device, but may have two or one of these three devices, or may additionally have other protective devices than the above three devices.

While preferred embodiments of the present invention have been described using specific terms, such description is for illustrative purposes only, and it is to be understood that changes and variations may be made without departing from the spirit or scope of the following claims.

1. A semiconductor device comprising:
a rectangular chip having four sides;
wires connected respectively to different external terminals; and
a bonding pad disposed along one of the four sides of said rectangular chip and directly connected to said wires for connection to said different external terminals.

2. A semiconductor device according to claim 1, wherein said bonding pad is of an elongate rectangular shape.

3. A semiconductor device according to claim 1, wherein said bonding pad has a plurality of unit pads each connectable to a single wire.

4. A semiconductor device according to claim 1, wherein a plurality of said bonding pads are disposed along said one of the four sides of said rectangular chip.

5. A multi-chip package comprising:
a stacked assembly of first and second semiconductor devices each comprising a semiconductor device according to claim 1;
wherein said first semiconductor device has a first pad as said bonding pad and said second semiconductor device having a second pad as said bonding pad, and said first semiconductor device are positionally displaced with respect to said second semiconductor device in a direction perpendicular to the side along which said bonding pad is disposed, such that said first pad and said second pad are exposed;
said first pad is connected to a first wire bonded to one of said external terminals; and
said second pad is connected to said first pad by a second wire which is different from said first wire.

6. A multi-chip package according to claim 5, further comprising:
a third semiconductor device having said one of the external terminals and stacked on said first semiconductor device such that said first pad is exposed.

7. A multi-chip package according to claim 6, wherein said first pad is electrically insulated from an internal circuit of said first semiconductor device.

8. A multi-chip package according to claim 6, wherein said first and second semiconductor devices comprise memories, respectively, and said third semiconductor device comprises a device for storing information in said first and second semiconductor devices.

9. A multi-chip package according to claim 8, wherein at least one of said first and second semiconductor devices comprises:
a storage area divided into a plurality of banks;
a peripheral circuit connected to said banks and spaced equally from said banks, for processing signals transferred between said banks and an external circuit; and
buffers connected to said peripheral circuit and positioned more closely to said pads than said peripheral circuit, for amplifying output signals to be outputted to said external circuit.

10. A multi-chip package according to claim 9, wherein at least one of said first and second semiconductor devices comprises:
an interconnect connecting said pads which are supplied with signals from said external circuit to said peripheral circuit;
a first input protection circuit connected to said interconnect more closely to said peripheral circuit than said banks; and
a second input protection circuit connected to said interconnect more closely to said pads than said first input protection circuit and disposed between said pads and said banks.

11. A multi-chip package according to claim 6, wherein said first and second semiconductor devices comprise memories, respectively, and said third semiconductor device comprises a memory control device for controlling said memories.

12. A multi-chip package according to claim 11, wherein said memory control device comprises a central processing unit or a memory controller.

13. A multi-chip package according to claim 6, wherein said first and second semiconductor devices comprise nonvolatile memories, respectively, and said third semiconductor device comprises a random access memory.

14. A method of wire bonding between a first semiconductor device having a first pad having wire bonding areas capable of directly bonding a plurality of wires thereto and a second semiconductor device having a second pad having a wire bonding area capable of bonding at least one wire thereto, comprising the steps of:
bonding a first wire connected to an external terminal to said first pad;
bonding a second wire to said first pad; and
bonding the second wire to said second pad.
